(19) United States
(12) Patent Application Publication
(10) Pub. No.: US 2026/0122955 A1
(43) Pub. Date: Apr. 30, 2026

(54) FINFET STRUCTURE AND METHOD OF FABRICATING THE SAME

(71) Applicant: UNITED MICROELECTRONICS CORP., Hsin-Chu City (TW)

(72) Inventors: Ya-Hsin Huang, Tainan City (TW); Chun-Wen Cheng, New Taipei City (TW); Ming-Hua Tsai, Tainan City (TW); Chun-Lin Chen, Tainan City (TW); Chin-Chia Kuo, Tainan City (TW); Ming-Hsiang Tu, Tainan City (TW); Yung-Fang Yang, Chiayi City (TW)

(73) Assignee: UNITED MICROELECTRONICS CORP., Hsin-Chu City (TW)

(21) Appl. No.: 18/967,599

(22) Filed: Dec. 3, 2024

(30) Foreign Application Priority Data
Oct. 29, 2024 (TW) 113141187

(51) Int. Cl. H10D 30/62; H10D 30/01; H10D 64/01

(52) U.S. Cl. CPC H10D 30/62; H10D 30/024; H10D 64/017

(57) ABSTRACT

An FinFET structure includes a semiconductor substrate. A fin structure protrudes from the semiconductor substrate. A gate crosses the fin structure. A source region and a drain region are respectively disposed on the fin structure at two sides of the gate. The source region includes a first epitaxial layer and a third epitaxial layer respectively embedded in the fin structure. A first non-epitaxial region is defined as the fin structure between the first epitaxial layer and the third epitaxial layer. The drain region includes a second epitaxial layer and a fourth epitaxial layer respectively embedded in the fin structure. A second non-epitaxial region is defined as the fin structure between the second epitaxial layer and the fourth epitaxial layer. A first contact plug is disposed on the third epitaxial layer and a second contact plug is disposed on the fourth epitaxial layer.

### BACKGROUND OF THE INVENTION

### 1. Field of the Invention

The present invention relates to a fin field effect transistor (FinFET), and in particular to an FinFET having numerous epitaxial layers disposed in a source region and a drain region.

### 2. Description of the Prior Art

Semiconductor devices are used in a variety of electronic applications, such as personal computers, mobile phones, digital cameras, and other electronic equipment. Semiconductor device manufacturing processes typically include the sequential deposition of insulating or dielectric layers, conductive layers, and semiconductor layers on a semiconductor substrate. Then, a photolithography process is used to pattern each of the above material layers to form circuit components on the semiconductor substrate. Circuits are often fabricated on a single semiconductor wafer, and dices are separated by dicing the circuits along scribe lines. Each of the above-mentioned dices is usually packaged separately in a multi-chip module or other types of packages.

As the feature size of transistors continues to shrink to achieve higher circuit density and higher performance, FinFETs are widely used in integrated circuits. Because FinFETs are three-dimensional, therefore circuit control can be improved, current leakage can be reduced and the gate length can be shortened by using FinFETs.

However, FinFETS still have the problem of uncompleted formation of the material layers in the drain region and the source region.

### SUMMARY OF THE INVENTION

In view of the above, the present invention provides a method of forming numerous separate epitaxial layers in the source region and the drain electrode to solve the problem of being unable to fill up the epitaxial layer in the source region and the drain region..

According to a preferred embodiment of the present invention, an fin FinFET structure includes a semiconductor substrate. A fin structure protrudes from the semiconductor substrate. A gate crosses the fin structure. A source region is disposed on the fin structure at one side of the gate. The source region includes a first epitaxial layer, a third epitaxial layer and a first non-epitaxial region. The first epitaxial layer is embedded in the fin structure. The third epitaxial layer is embedded in the fin structure, and wherein the third epitaxial layer does not connect to the first epitaxial layer. The first non-epitaxial region is defined as the fin structure between the first epitaxial layer and the third epitaxial layer. A drain region is disposed on the fin structure at another side of the gate, wherein the drain region includes a second epitaxial layer, a fourth epitaxial layer and a second non-epitaxial region. The second epitaxial layer is embedded in the fin structure. The fourth epitaxial layer is embedded in the fin structure, and wherein the fourth epitaxial layer does not connect to the second epitaxial layer. The second non-epitaxial region is defined as the fin structure between the second epitaxial layer and the fourth epitaxial layer. A first contact plug is disposed on the third epitaxial layer. A second contact plug is disposed on the fourth epitaxial layer.

A fabricating method of an FinFET structure includes forming an FinFET structure, wherein the FinFET includes a semiconductor substrate. A fin structure protrudes from the semiconductor substrate. A gate crosses the fin structure. A source region is disposed on the fin structure at one side of the gate. The source region includes a first epitaxial layer, a third epitaxial layer and a first non-epitaxial region. The first epitaxial layer is embedded in the fin structure. The third epitaxial layer is embedded in the fin structure, and wherein the third epitaxial layer does not connect to the first epitaxial layer. The first non-epitaxial region is defined as the fin structure between the first epitaxial layer and the third epitaxial layer. A drain region is disposed on the fin structure at another side of the gate, wherein the drain region includes a second epitaxial layer, a fourth epitaxial layer and a second non-epitaxial region. The second epitaxial layer is embedded in the fin structure. The fourth epitaxial layer is embedded in the fin structure, and wherein the fourth epitaxial layer does not connect to the second epitaxial layer. The second non-epitaxial region is defined as the fin structure between the second epitaxial layer and the fourth epitaxial layer. A first contact plug is disposed on the third epitaxial layer. A second contact plug is disposed on the fourth epitaxial layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 depicts a top view of an FinFET according to a first preferred embodiment of the present invention.

FIG. 2 depicts a sectional view taken along line AA′ in FIG. 1.

FIG. 3 depicts an FinFET according to the second preferred embodiment of the present invention.

FIG. 4 depicts an FinFET according to the third preferred embodiment of the present invention.

FIG. 5 depicts an FinFET according to the fourth preferred embodiment of the present invention.

FIG. 6 depicts an FinFET according to the fifth preferred embodiment of the present invention.

FIG. 7 depicts an FinFET according to the sixth preferred embodiment of the present invention.

FIG. 8 depicts a fabricating method of an FinFET according to the first preferred embodiment.

FIG. 9 depicts a FinFET according to an exemplary embodiment of the present invention.

### DETAILED DESCRIPTION

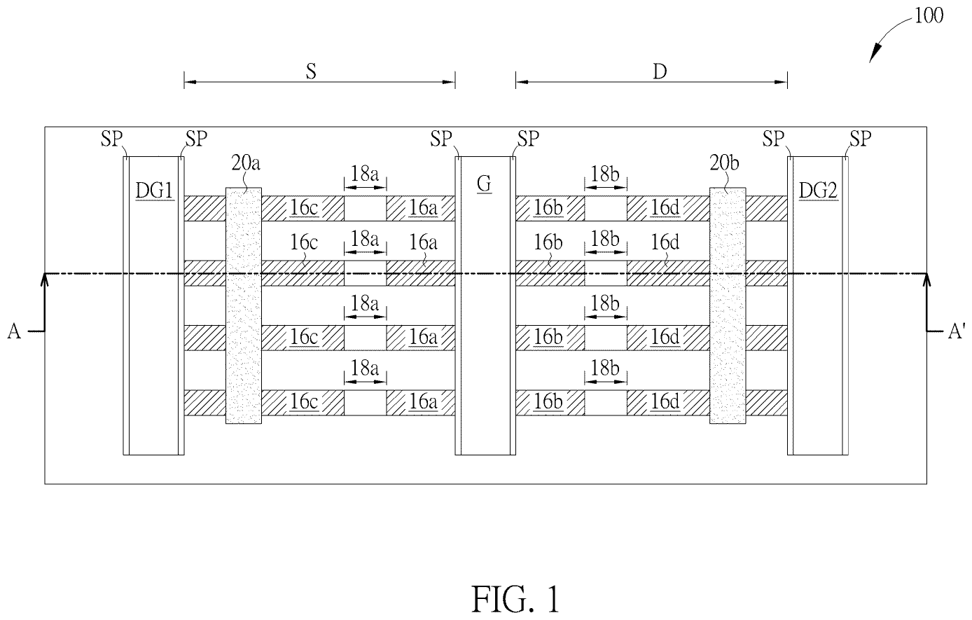

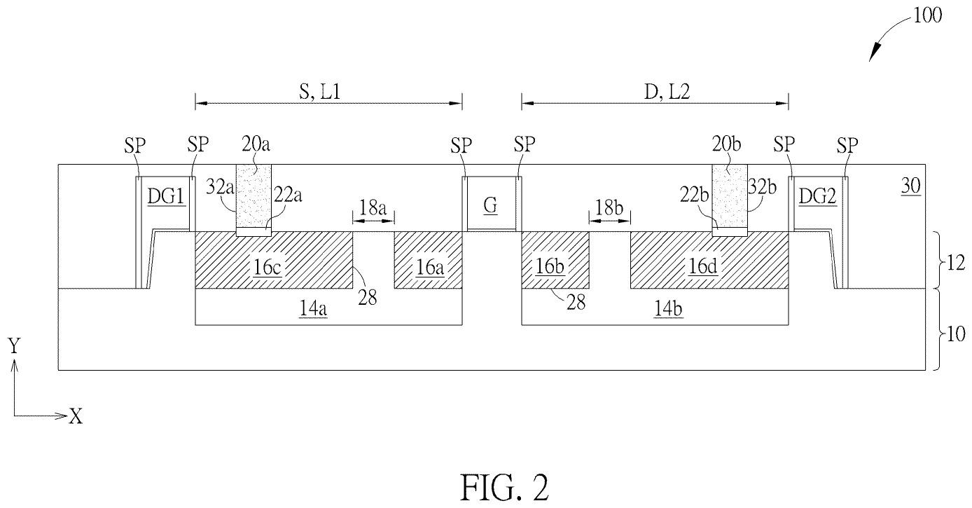

FIG. 1 depicts a top view of an FinFET according to a first preferred embodiment of the present invention. FIG. 2 depicts a sectional view taken along line AA′ in FIG. 1.

As shown in FIG. 1 and FIG. 2, an FinFET 100 includes a semiconductor substrate 10. The semiconductor substrate 10 includes a silicon substrate, a germanium substrate, a gallium arsenide substrate, a silicon germanium substrate, an indium phosphide substrate, a gallium nitride substrate, a silicon carbide substrate or a silicon on insulator substrate. A fin structure 12 protrudes from the semiconductor substrate 10. A gate G crosses the fin structure 12. Two spacers SP are respectively disposed at two sides of the gate G. A source region S is disposed on the fin structure 12 at one side of the gate G. A drain region D is disposed on the fin structure 12 at the other side of the gate G. The source region S includes a first doping well 14a, a first epitaxial layer 16a, a first non-epitaxial region 18a and a third epitaxial layer 16c. The first epitaxial layer 16a and the third epitaxial layer 16c are both embedded in the fin structure 12. The third epitaxial layer 16c and the first epitaxial layer 16a do not connect to each other. The first non-epitaxial region 18a is defined as the fin structure 12 between the first epitaxial layer 16a and the third epitaxial layer 16c. The first doping well 14a is disposed in the first non-epitaxial region 18a and below the first epitaxial layer 16a and the third epitaxial layer 16c.

The drain region D includes a second doping well 14b, a second epitaxial layer 16b, a second non-epitaxial region 18b and a fourth epitaxial layer 16d. The second epitaxial layer 16b and the fourth epitaxial layer 16d are embedded in the fin structure 12. The second epitaxial layer 16b and the fourth epitaxial layer 16d do not connect to each other. The second non-epitaxial region 18b is defined as the fin structure 12 between the second epitaxial layer 16b and the fourth epitaxial layer 16d. The second doping well 14b is disposed in the second non-epitaxial region 18 and below the second epitaxial layer 16b and the fourth epitaxial layer 16d.

A vertical direction Y is perpendicular to the top surface of the fin structure 12. Along the vertical direction Y, the edge of the first epitaxial layer 16a overlaps the spacer SP. The edge of the second epitaxial layer 16b overlaps the spacer SP. That is, the first epitaxial layer 16a and the second epitaxial layer 16b are adjacent to the gate G. There is no non-epitaxial region between the first epitaxial layer 16a and the gate G. There is also no non-epitaxial region between the second epitaxial layer 16b and the gate G.

Moreover, a first contact plug 20a is disposed on the third epitaxial layer 16c. A second contact plug 20b is disposed on the fourth epitaxial layer 16d. A first silicide 22a is disposed only between the first contact plug 20a and the third epitaxial layer 16c. A second silicide 22b is disposed only between the second contact plug 20b and the fourth epitaxial layer 16d. There is no silicide on the first epitaxial layer 16a, the second epitaxial layer 16b, the first non-epitaxial region 18a and the second non-epitaxial region 18b. There is also no silicide on the third epitaxial layer 16c which is not covered by the first contact plug 20a, and no silicide on the fourth epitaxial layer 16d which is not covered by the second contact plug 20b. According to a preferred embodiment of the present invention, along a horizontal direction X, a length of the fourth epitaxial layer 16d is greater than a length of the second epitaxial layer 16b, and a length of the third epitaxial layer 16c is greater than a length of the first epitaxial layer 16a. Therefore, by disposing the second contact plug 20b on the fourth epitaxial layer 16d and the first contact plug 20a on the third epitaxial layer 16c can allow a greater process window for the fabricating process of the contact plugs.

A first dummy gate DG1 is disposed at an end of the fin structure 12 and adjacent to the source region S. A second dummy gate DG2 is disposed at the other end of the fin structure 12 and adjacent to the drain region D. The first dummy gate DG1 and the second dummy gate DG2 do not have the function of controlling the transistor switch. They are formed only to balance the loading effect.

In the first preferred embodiment, a first distance L1 is disposed between the gate G to an edge of the source region S, a second distance L2 is disposed between the gate G to an edge of the drain region D, and the second distance L2 is equal to the first distance L1. That is, along the horizontal direction X, the source region S and the drain region D have the same length. Moreover, based on whether the fin field effect transistor 100 is a P-type transistor or an N-type transistor, the doping well and the epitaxial layer will have different conductive types. For example, when the FinFET 100 is a P-type transistor, the first epitaxial layer 16a, the second epitaxial layer 16b, the third epitaxial layer 16c and the fourth epitaxial layer 16d are preferably silicon germanium (SiGe). Silicon germanium can be optionally doped with P-type dopants. Meanwhile, the conductive type of the first doping well 14a and the second doping well 14b are preferably N-type. On the other hand, when the FinFET 100 is an N-type transistor, the first epitaxial layer 16a, the second epitaxial layer 16b, the third epitaxial layer 16c and the fourth epitaxial layer 16d are preferably silicon phosphide (SiP) or silicon carbide (SiC). Silicon phosphide and silicon carbide can be optionally doped with N-type dopants. The conductive type of the first doping well 14a and the second doping well 14b are preferably P-type. In addition, based on the description mentioned above,-the FinFET 100 has a symmetrical structure.

When the material of the fin structure 12 is silicon, the larger the areas of the first non-epitaxial region 18a and the second non-epitaxial region 18b are, the higher the resistance of the source region S and the drain region D. In other words, the smaller the areas of the first epitaxial layer 16a, the second epitaxial layer 16b, the third epitaxial layer 16c and the fourth epitaxial layer 16d are, the higher the resistance of the source region S and the drain region D. In this way, the on-resistance of the FinFET 100 can be controlled by adjusting the areas of the first non-epitaxial region 18a and the second non-epitaxial region 18c.

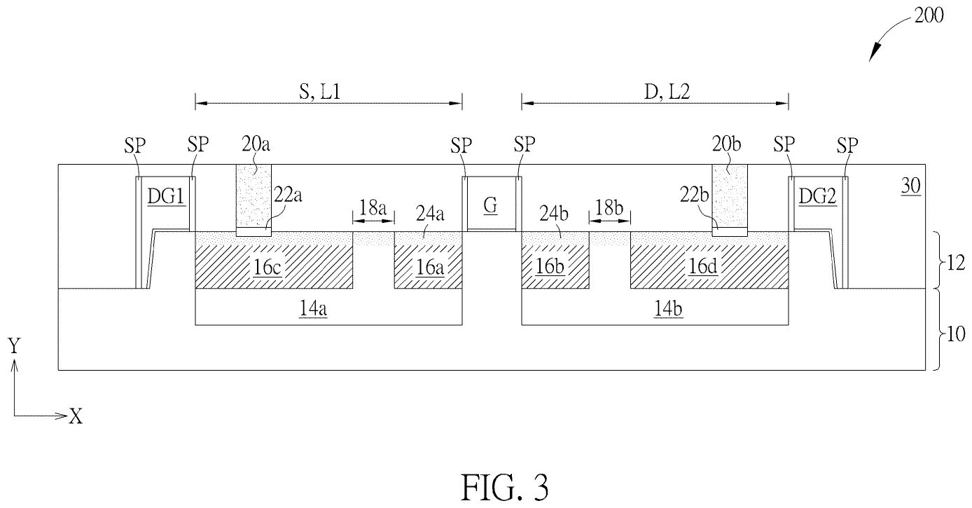

FIG. 3 depicts an FinFET according to the second preferred embodiment of the present invention, wherein elements which are substantially the same as those in the first preferred embodiment are denoted by the same reference numerals; an accompanying explanation is therefore omitted.

The FinFET 200 has a symmetrical structure. The differences between the second preferred embodiment and the first preferred embodiment are that the second preferred embodiment further includes a source doping region 24a and a drain doping region 24b. The source doping region 24a is disposed in the first epitaxial layer 16a, the third epitaxial layer 16c and the first non-epitaxial region 18a. The drain doping region 24b is disposed in the second epitaxial layer 16b, the fourth epitaxial layer 16d and the second non-epitaxial region 18b. When the FinFET 200 is an N-type transistor, the conductivity type of the source doping region 24a and the drain doping region 24b is N type. When the FinFET 200 is a P-type transistor, the conductivity type of the source doping region 24a and the drain doping region 24b is P type. Other components are the same as those in the first preferred embodiment and the description is therefore omitted.

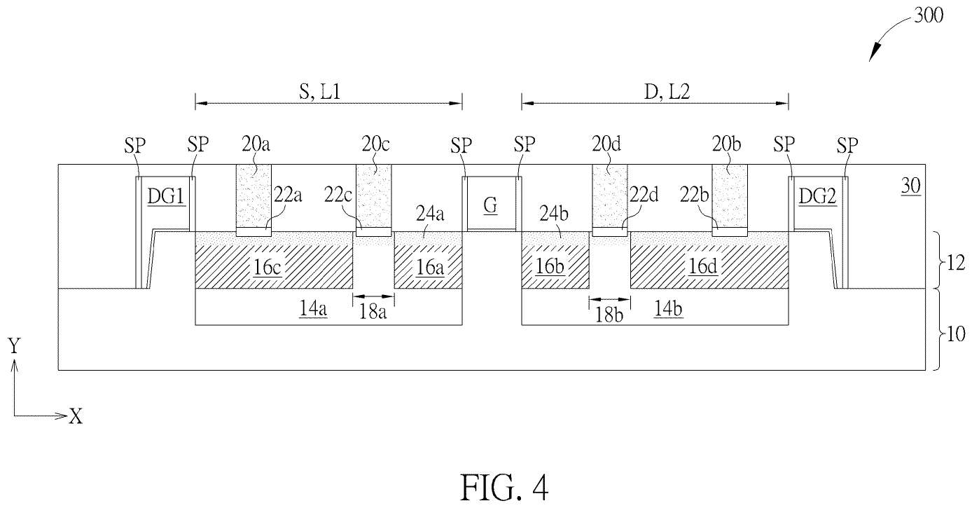

FIG. 4 depicts an FinFET according to the third preferred embodiment of the present invention, wherein elements which are substantially the same as those in the second preferred embodiment are denoted by the same reference numerals; an accompanying explanation is therefore omitted.

The FinFET 300 is a symmetrical structure. The differences between the third preferred embodiment and the second preferred embodiment are that the third preferred embodiment further includes a first dummy contact plug 20c and a second dummy contact plug 20d. The first dummy contact plug 20c is disposed on the first non-epitaxial region 18a. The second dummy contact plug 20d is disposed on the second non-epitaxial region 18b. A third silicide 22c is disposed between the first dummy contact plug 20c and the first non-epitaxial region 18a. A fourth silicide 22d is disposed between the second dummy contact plug 20d and the second non-epitaxial region 18b. The first dummy contact plug 20c and the second dummy contact plug 20d are not connected to other wires and therefore they do not have the function of transmitting signals. The first dummy contact plug 20c and the second dummy contact plug 20d are formed only to balance the load effect during the fabricating process. Other components are the same as those in the first preferred embodiment and the description is therefore omitted.

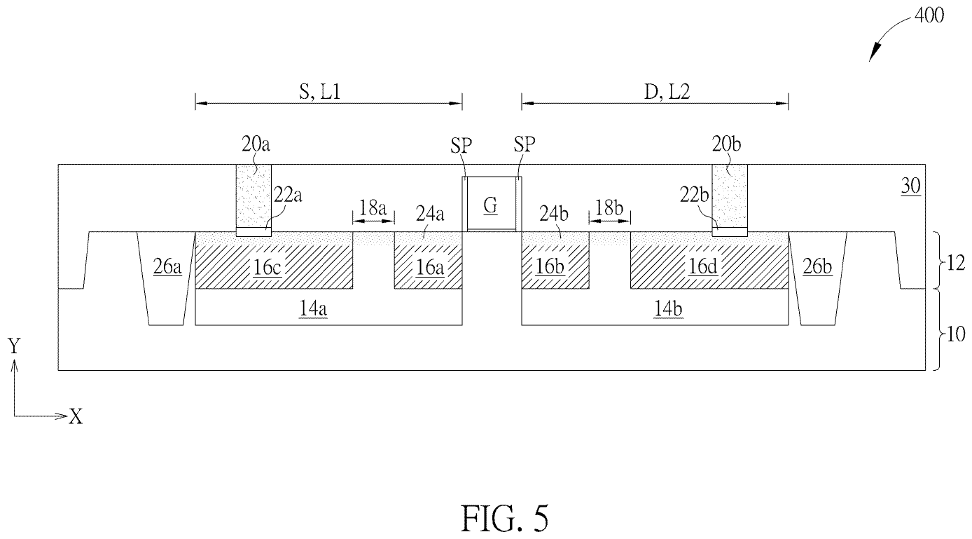

FIG. 5 depicts an FinFET according to the fourth preferred embodiment of the present invention, wherein elements which are substantially the same as those in the second preferred embodiment are denoted by the same reference numerals; an accompanying explanation is therefore omitted.

The FinFET 400 is a symmetrical structure. The differences between the fourth preferred embodiment and the second preferred embodiment are that in the fourth preferred embodiment, there are no the first dummy gate DG1 and the second dummy gate DG2. Besides, in the fourth preferred embodiment, single diffusion breaks 26a/26b are respectively disposed in the source region S and the drain region D. The single diffusion blocks 26a/26b are used to define the range of the source region S and the drain region D. Other components are the same as those in the second preferred embodiment and the description is therefore omitted.

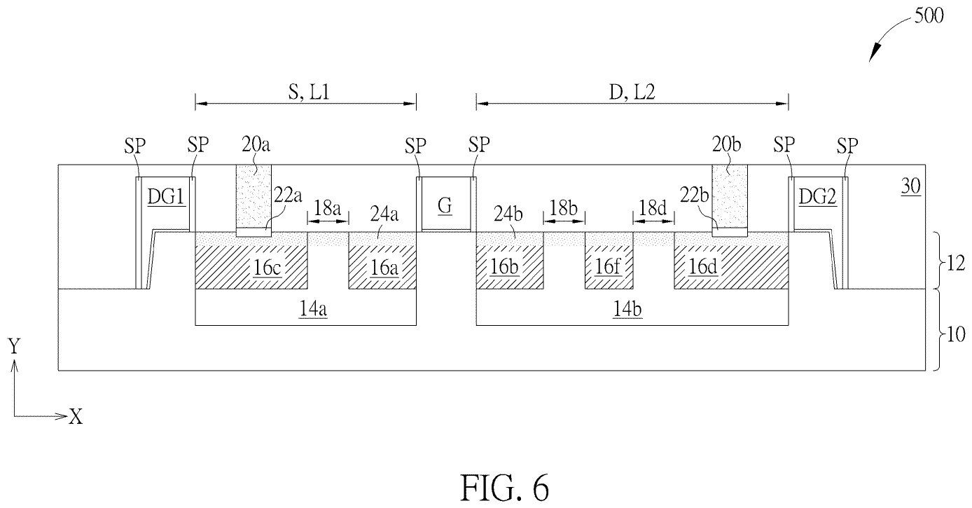

FIG. 6 depicts an FinFET according to the fifth preferred embodiment of the present invention, wherein elements which are substantially the same as those in the second preferred embodiment are denoted by the same reference numerals; an accompanying explanation is therefore omitted.

The FinFET 500 is an asymmetrical structure. The differences between the fifth preferred embodiment and the second preferred embodiment are that the first distance L1 which from the gate G to the edge of the source region S is different from the second distance L2 which is from the gate G to the edge of the drain region D. The second distance L2 is greater than the first distance L1. That is, along the horizontal direction X, the length of the drain region D is greater than the length of the source region S. Because the length of the drain region D is greater, more epitaxial layers can be arranged in the drain region D. In this way, the drain region D can be used as a high voltage signal input terminal. Furthermore, the number of epitaxial layers in the source region S and the number of epitaxial layers in the drain region D can be different. For example, in the fifth preferred embodiment, there are three epitaxial layers in the drain region D. The three epitaxial layers, namely, the second epitaxial layer 16b, the fourth epitaxial layer 16d, and the sixth epitaxial layer 16f are not connected to each other. On the other hand, there are only two epitaxial layers in the source region S, namely the first epitaxial layer 16a and the third epitaxial layer 16c. The fin structure 12 between the second epitaxial layer 16b and the sixth epitaxial layer 16f is defined as a second non-epitaxial region 18b. The fin structure 12 between the sixth epitaxial layer 16f and the fourth epitaxial layer 16d is defined as a fourth non-epitaxial region 18d. Other components are the same as those in the second preferred embodiment and the description is therefore omitted.

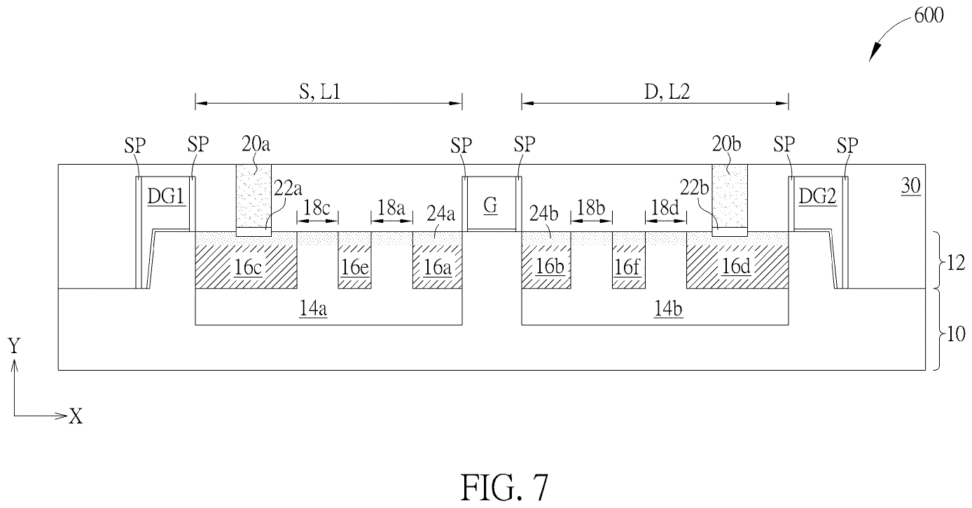

FIG. 7 depicts an FinFET according to the sixth preferred embodiment of the present invention, wherein elements which are substantially the same as those in the second preferred embodiment are denoted by the same reference numerals; an accompanying explanation is therefore omitted.

The FinFET 600 is a symmetrical structure. The differences between the sixth preferred embodiment and the second preferred embodiment are that there are three epitaxial layers respectively disposed in the source region S and the drain region D. The three epitaxial layers in the source region S are not connected to each other, and the three epitaxial layers in the drain region D are not connected to each other as well. Along the horizontal direction X, the length of the drain region D is still the same as the length of the source region S. That is, the first distance L1 is equal to the second distance L2. In details, there are the first epitaxial layer 16a, the third epitaxial layer 16c and the fifth epitaxial layer 16e disposed the source region S. There are the second epitaxial layer 16b, the fourth epitaxial layer 16d and the sixth epitaxial layer 16f disposed in the drain region D. The fin structure 12 between the second epitaxial layer 16b and the sixth epitaxial layer 16f is defined as a second non-epitaxial region 18b. The fin structure 12 between the sixth epitaxial layer 16f and the fourth epitaxial layer 16d is defined as a fourth non-epitaxial region 18d. The fin structure 12 between the first epitaxial layer 16a and the fifth epitaxial layer 16e is defined as a first non-epitaxial region 16a. The fin structure 12 between the fifth epitaxial layer 16e and the third epitaxial layer 16c is defined as a third non-epitaxial region 16c. Other components are the same as those in the second preferred embodiment and the description is therefore omitted.

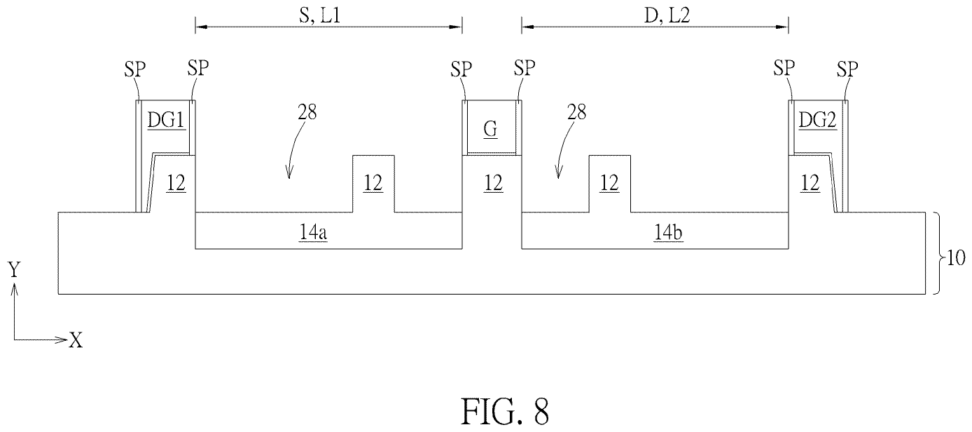

FIG. 8 depicts a fabricating method of an FinFET according to the first preferred embodiment, wherein elements which are substantially the same as those in the first preferred embodiment are denoted by the same reference numerals; an accompanying explanation is therefore omitted. As shown in FIG. 8, a semiconductor substrate 10 is provided. Then, the semiconductor substrate 10 is etched to define a fin structure 12 on the semiconductor substrate 10. Next, a gate G, a first dummy gate DG1 and a second dummy gate DG2 are formed to cross the fin structure 12 at the same time. Later, an ion implantation process is performed to form ta first doping well 14a and a second doping well 14b in the fin structure 12 at two sides of the gate G. Subsequently, the fin structure 12 is patterned to form numerous recesses 28 in the fin structure 12. After that, as shown in FIG. 2, an epitaxial process is performed to form a first epitaxial layer 16a, a second epitaxial layer 16b, a third epitaxial layer 16c and a fourth epitaxial layer 16d to respectively fill the recesses 28. Next, a dielectric layer 30 is formed to cover the fin structure 12. Later, the dielectric layer 30 is etched to form a first contact hole 32a and a second contact hole 32b to respectively expose the third epitaxial layer 16c and the fourth epitaxial layer 16d. Then, a first silicide 22a and a second silicide 22b are formed on the exposed third epitaxial layer 16c and the exposed fourth epitaxial layer 16d. Subsequently, a first contact plug 20a and a second contact plug 20b are formed. The first contact plug 20a fills in the first contact hole 32a. The second contact plug 20b fills in the second contact hole 32b. Now, the FinFET 100 in FIG. 2 is completed.

Moreover, the source doping region 24a and the drain doping region 24b of the FinFET 200, the FinFET 300, the FinFET 400, the FinFET 500 and the FinFET 600 may be formed by an ion implantation process which is performed after forming the first epitaxial layer 16a, the second epitaxial layer 16b, the third epitaxial layer 16c, the fourth epitaxial layer 16d, the fifth epitaxial layer 16e (optional) and the sixth epitaxial layer 16f (optional) and before forming the dielectric layer 30. The first dummy contact plug 20c and the second dummy contact plug 20d of the FinFET 300 can be formed simultaneously with the first contact plug 20a and the second contact plug 20b by using the same fabricating steps. The single diffusion breaks 26a/26b of the FinFET 400 can be formed by etching the fin structure 12 followed by filling an insulating layer. The steps of forming the single diffusion breaks 26a/26b can be performed after forming the fin structure 12 and before forming the gate G. The fabricating method of different numbers of epitaxial layers in the FinFET 500 and the FinFET 600 can be performed by just adjusting the number of recesses 28. Different sizes of the first distance L1 and the second distance L2 of the FinFET 500 can be formed by adjusting the position of the gate G.

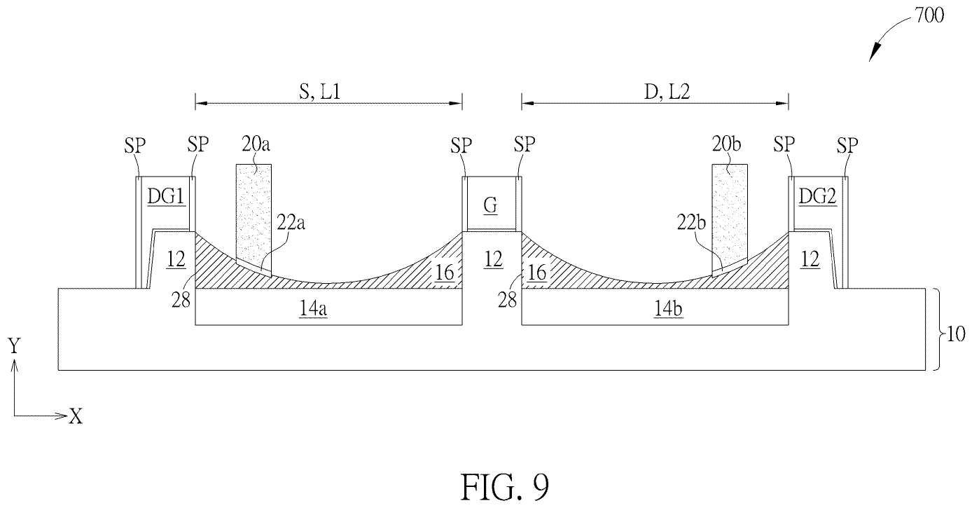

FIG. 9 depicts a FinFET according to an exemplary embodiment of the present invention, wherein elements which are substantially the same as those in the first preferred embodiment are denoted by the same reference numerals; an accompanying explanation is therefore omitted.

As shown in FIG. 9, the FinFET 700 has no non-epitaxial region. Therefore, the epitaxial layer 16 needs to fill the entire source region S and the drain region D. As a result, the recess 28 to be filled with the epitaxial layer 16 has a larger opening. Therefore, there will be a problem that the epitaxial layer 16 can't fill up the recess 28.

In the present invention, numerous recesses are formed in the source region and the drain region, so the opening of each recess become smaller, and the epitaxial layer can fill up each recess. Moreover, the on-resistance of the FinFET can be adjusted through the size of the non-epitaxial region. Furthermore, the on-resistance of the FinFET can also be adjusted by optionally forming the source doping region and the drain doping region. Therefore, the FinFET of the present invention has adjustable on-resistance, which is beneficial for the FinFET of the present invention to be applied to electrostatic protection components.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A fin field-effect transistor (FinFET) structure, comprising:
a semiconductor substrate;
a fin structure protruding from the semiconductor substrate;
a gate crossing the fin structure;
a source region disposed on the fin structure at one side of the gate, wherein the source region comprises:
a first epitaxial layer embedded in the fin structure;
a third epitaxial layer embedded in the fin structure, and wherein the third epitaxial layer does not connect to the first epitaxial layer; and
a first non-epitaxial region which is defined as the fin structure between the first epitaxial layer and the third epitaxial layer;
a drain region disposed on the fin structure at another side of the gate, wherein the drain region comprises:
a second epitaxial layer embedded in the fin structure;
a fourth epitaxial layer embedded in the fin structure, and wherein the fourth epitaxial layer does not connect to the second epitaxial layer; and
a second non-epitaxial region which is defined as the fin structure between the second epitaxial layer and the fourth epitaxial layer;
a first contact plug disposed on the third epitaxial layer; and
a second contact plug disposed on the fourth epitaxial layer.

2. The FinFET structure of claim 1, further comprising:
a first silicide only disposed between the first contact plug and the third epitaxial layer; and
a second silicide only disposed between the second contact plug and the fourth epitaxial layer.

3. The FinFET structure of claim 1, wherein there is no silicide on the first epitaxial layer, the second epitaxial layer, the first non-epitaxial region and the second non-epitaxial region.

4. The FinFET structure of claim 1, further comprising:
a source doping region disposed in the first epitaxial layer, the third epitaxial layer and the first non-epitaxial region; and
a drain doping region disposed in the second epitaxial layer, the fourth epitaxial layer and the second non-epitaxial region.

5. The FinFET structure of claim 1, wherein a first distance is disposed between the gate to an edge of the source region, a second distance is disposed between the gate to an edge of the drain region, and the second distance is greater than the first distance.

6. The FinFET structure of claim 1, further comprising:
a fifth epitaxial layer embedded within the source region of the fin structure and disposed between the first epitaxial layer and the third epitaxial layer, wherein the first non-epitaxial region is disposed between the first epitaxial layer and the fifth epitaxial layer; and
a sixth epitaxial layer embedded within the drain region of the fin structure and disposed between the second epitaxial layer and the fourth epitaxial layer, wherein the second non-epitaxial region is disposed between the second epitaxial layer and the sixth epitaxial layer.

7. The FinFET structure of claim 1, further comprising:
a first dummy gate disposed at an end of the fin structure; and
a second dummy gate disposed at another end of the fin structure.

8. The FinFET structure of claim 1, further comprising two spacers disposed at two sides of the gate, wherein a vertical direction perpendicular to a top surface of the fin structure, along the vertical direction, an edge of the first epitaxial layer overlaps one of the two spacers, and along the vertical direction, an edge of the second epitaxial layer overlaps the other one of the two spacers.

9. The FinFET structure of claim 1, further comprising:
M number of (a) fifth epitaxial layer(s) embedded within the fin structure and disposed between the first epitaxial layer and the third epitaxial layer, wherein each of the M number of the fifth epitaxial layer(s) does not contact each other, M is an integer and M is greater than or equal to 0; and
N number of (a) sixth epitaxial layer(s) embedded within the fin structure and disposed between the second epitaxial layer and the fourth epitaxial layer, wherein each of the N number of the sixth epitaxial layer(s) does not contact each other, N is an integer, N is greater than or equal to 0, and N does not equal to N.

10. The FinFET structure of claim 1, further comprising:
a first dummy contact plug disposed on the first non-epitaxial region; and
a second dummy contact plug disposed on the second non-epitaxial region.

11. A fabricating method of a fin field-effect transistor (FinFET) structure, comprising:
forming an FinFET structure, wherein the FinFET comprises:
a semiconductor substrate;
a fin structure protruding from the semiconductor substrate;
a gate crossing the fin structure;
a source region disposed on the fin structure at one side of the gate, wherein the source region comprises:
a first epitaxial layer embedded in the fin structure;
a third epitaxial layer embedded in the fin structure, and wherein the third epitaxial layer does not connect to the first epitaxial layer; and
a first non-epitaxial region which is defined as the fin structure between the first epitaxial layer and the third epitaxial layer;
a drain region disposed on the fin structure at another side of the gate, wherein the drain region comprises:
a second epitaxial layer embedded in the fin structure;
a fourth epitaxial layer embedded in the fin structure, and wherein the fourth epitaxial layer does not connect to the second epitaxial layer; and
a second non-epitaxial region which is defined as the fin structure between the second epitaxial layer and the fourth epitaxial layer;
a first contact plug disposed on the third epitaxial layer; and
a second contact plug disposed on the fourth epitaxial layer.

12. The fabricating method of an FinFET structure of claim 11, further comprising:
forming a first silicide only disposed between the first contact plug and the third epitaxial layer; and
forming a second silicide only disposed between the second contact plug and the fourth epitaxial layer.

13. The fabricating method of an FinFET structure of claim 11, wherein there is no silicide on the first epitaxial layer, the second epitaxial layer, the first non-epitaxial region and the second non-epitaxial region.

14. The fabricating method of an FinFET structure of claim 11, further comprising:
forming a source doping region disposed in the first epitaxial layer, the third epitaxial layer and the first non-epitaxial region; and
forming a drain doping region disposed in the second epitaxial layer, the fourth epitaxial layer and the second non-epitaxial region.

15. The fabricating method of an FinFET structure of claim 11, wherein a first distance is disposed between the gate to an edge of the source region, a second distance is disposed between the gate to an edge of the drain region, and the second distance is greater than the first distance.

16. The fabricating method of an FinFET structure of claim 11, further comprising:
forming a fifth epitaxial layer embedded within the source region of the fin structure and disposed between the first epitaxial layer and the third epitaxial layer, wherein the first non-epitaxial region is disposed between the first epitaxial layer and the fifth epitaxial layer; and
forming a sixth epitaxial layer embedded within the drain region of the fin structure and disposed between the second epitaxial layer and the fourth epitaxial layer, wherein the second non-epitaxial region is disposed between the second epitaxial layer and the sixth epitaxial layer.

17. The fabricating method of an FinFET structure of claim 11, further comprising:
forming a first dummy gate disposed at an end of the fin structure; and
forming a second dummy gate disposed at another end of the fin structure.

18. The fabricating method of an FinFET structure of claim 11, further comprising forming two spacers disposed at two sides of the gate, wherein a vertical direction perpendicular to a top surface of the fin structure, along the vertical direction, an edge of the first epitaxial layer overlaps one of the two spacers, and along the vertical direction, an edge of the second epitaxial layer overlaps the other one of the two spacers.

19. The fabricating method of an FinFET structure of claim 11, further comprising:
forming M number of (a) fifth epitaxial layer(s) embedded within the fin structure and disposed between the first epitaxial layer and the third epitaxial layer, wherein each of the M number of the fifth epitaxial layer(s) does not contact each other, M is an integer and M is greater than or equal to 0; and
forming N number of (a) sixth epitaxial layer(s) embedded within the fin structure and disposed between the second epitaxial layer and the fourth epitaxial layer, wherein each of the N number of the sixth epitaxial layer(s) does not contact each other, N is an integer, N is greater than or equal to 0, and N does not equal to N.

20. The fabricating method of an FinFET structure of claim 11, further comprising:
forming a first dummy contact plug disposed on the first non-epitaxial region; and
forming a second dummy contact plug disposed on the second non-epitaxial region.
